(19) United States
(12) Patent Application Publication
(10) Pub. No.: US 2023/0010490 A1
(43) Pub. Date: Jan. 12, 2023

(54) WAVELENGTH BEAM COMBINING SYSTEM

(71) Applicant: Panasonic Holdings Corporation, Osaka (JP)

(72) Inventor: Kenya YAMASHITA, Hyogo (JP)

(21) Appl. No.: 17/810,448

(22) Filed: Jul. 1, 2022

(30) Foreign Application Priority Data
Jul. 7, 2021 (JP) 2021-112783

(51) Int. Cl. G02B 27/10

(52) U.S. Cl. CPC G02B 27/1086; G02B 27/1006

(57) ABSTRACT

A wavelength beam combining system includes: at least one laser diode bar that includes a plurality of emitters arranged in a row from a first end side to a second end side, and a heating element placed on the second end side with respect to the plurality of emitters; an optical element that condenses beams emitted from the plurality of emitters; a diffraction grating; an external resonance mirror; and a controlling apparatus that controls power supplied to the plurality of emitters and the heating element. The laser diode bar is placed so that a locked wavelength for an emitter located on the second end side is longer than the locked wavelength for an emitter located on the first end side. The controlling apparatus controls the power supplied to the heating element so that the heating element has a higher temperature than the plurality of emitters.

### CROSS REFERENCE TO RELATED APPLICATIONS

This application is entitled and claims the benefit of Japanese Patent Application No. 2021-112783 filed on Jul. 7, 2021, the disclosure of which including the specification, drawings and abstract is incorporated herein by reference in its entirety.

### TECHNICAL FIELD

The present disclosure relates to a wavelength beam combining system.

### BACKGROUND ART

A wavelength beam combining (WBC) system has been known as a system to obtain a high-power laser beam by combining a plurality of beams with different wavelengths to a single point. The wavelength beam combining system is disclosed in Patent Literature 1, for example.

The wavelength beam combining system includes, for example, a laser diode (LD) bar, a beam twister lens unit (BTU), a diffraction grating, and an external resonance mirror.

The laser diode bar emits beams from a plurality of emitters. The plurality of beams emitted from the laser diode bar are focused onto the diffraction grating through the beam twister lens unit. The diffraction grating diffracts the incident beam at a diffraction angle determined by the wavelength and emits the beam. The beam emitted from the diffraction grating is incident on the external resonance mirror. The external resonance mirror is a partially transparent mirror, and vertically reflects some of the incident beam in the direction of the diffraction grating. The diffraction grating feeds back the beam reflected by the external resonance mirror to the laser diode bar. Oscillation then occurs between the laser diode bar and the external resonance mirror due to external resonance, and a laser beam is emitted from the wavelength beam combining system.

The oscillation due to external resonance occurs only for a beam with a wavelength (locked wavelength) uniquely determined by the positional relationship of individual emitters of the laser diode bar, the diffraction grating, and the external resonance mirror.

### CITATION LIST

### Patent Literature

PTL 1

Japanese Patent Application Laid-Open No. 2015-106707

### SUMMARY OF INVENTION

### Technical Problem

Incidentally, a laser diode bar with a plurality of emitters tends to have a temperature difference in the array direction of the emitters. The wavelengths of the beams emitted from the plurality of emitters vary with temperature. No oscillation occurs due to external resonance without the locked wavelength in a range of the wavelengths of the beams. When no oscillation occurs due to external resonance in some of the plurality of emitters, the intensity of a laser beam emitted from the wavelength beam combining system is reduced.

An objective of the present disclosure is to prevent reduction in the intensity of a laser beam emitted from a wavelength beam combining system.

### Solution to Problem

A wavelength beam combining system according to an aspect of the present disclosure includes: at least one laser diode bar that includes a plurality of emitters arranged in a row from a first end side to a second end side, and a heating element placed on the second end side with respect to the plurality of emitters; an optical element that condenses a beam emitted from each of the plurality of emitters; a diffraction grating that diffracts the beam condensed by the optical element; an external resonance mirror that causes external resonance by feeding back, to the laser diode bar, a part of the beam diffracted by the diffraction grating; and a controlling apparatus that controls power to be supplied to the plurality of emitters and the heating element. The laser diode bar is placed in such a posture that a locked wavelength for at least one of the plurality of emitters located on the second end side is longer than the locked wavelength for at least one of the plurality of emitters located on the first end side, the locked wavelength causing oscillation due to the external resonance, and the controlling apparatus controls the power to be supplied to the heating element so that a temperature of the heating element is higher than temperatures of the plurality of emitters.

### Advantageous Effects of Invention

According to a wavelength beam combining system of the present disclosure, it is possible to prevent reduction in the intensity of a laser beam emitted from the wavelength beam combining system.

### BRIEF DESCRIPTION OF DRAWINGS

FIG. 1 is a schematic diagram of a wavelength beam combining system according to Embodiment 1 of the present disclosure;

FIG. 2 is a perspective view illustrating a configuration of one laser diode bar;

FIG. 3 illustrates a relationship between one laser diode bar and a diffraction grating;

FIG. 4 illustrates exemplary locked wavelengths for respective emitters of one laser diode bar;

FIG. 5 illustrates a relationship between the wavelength and intensity of a beam emitted from an emitter;

FIG. 6 illustrates a relationship between a gain peak wavelength and a locked wavelength of each emitter of a laser diode bar;

FIG. 7 illustrates another relationship between a gain peak wavelength and a locked wavelength of each emitter of a laser diode bar;

FIG. 8 is a plan view illustrating a schematic configuration of a laser diode bar according to Embodiment 1 of the present disclosure;

FIG. 9A is a side view illustrating the laser diode bar mounted;

FIG. 9B illustrates a variation of a conductive layer and an N-type electrode illustrated in FIG. 9A;

FIG. 10 illustrates a relationship between a gain peak wavelength and a locked wavelength of each emitter of the laser diode bar;

FIG. 11 is a plan view illustrating a schematic configuration of a laser diode bar according to Embodiment 2 of the present disclosure;

FIG. 12 is a side view illustrating the laser diode bar mounted;

FIG. 13 illustrates a relationship between a gain peak wavelength and a locked wavelength of each emitter of the laser diode bar;

FIG. 14 is a side view illustrating a schematic configuration of a laser diode bar according to Embodiment 3 of the present disclosure; and

FIG. 15 is a side view illustrating a schematic configuration of a laser diode bar according to Embodiment 4 of the present disclosure.

### DESCRIPTION OF EMBODIMENTS

### Embodiment 1

Hereinafter, embodiments of the present disclosure will be described in detail with reference to the accompanying drawings. First, the background that led to the present invention will be explained.

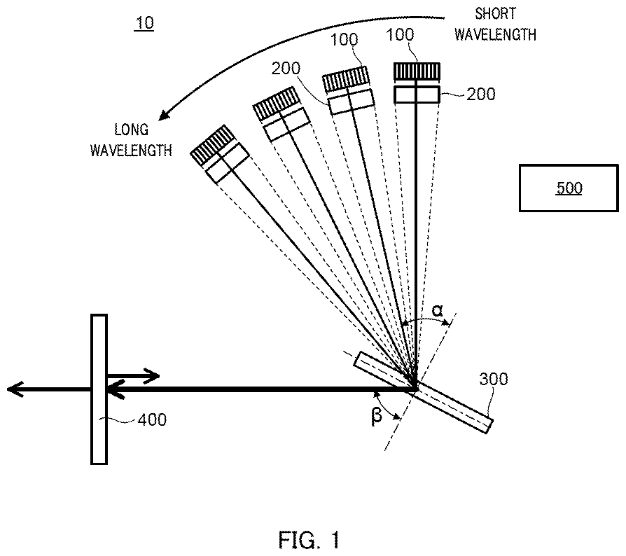

FIG. 1 is a schematic diagram of wavelength beam combining system (hereinafter, referred to as WBC system) 10. WBC system 10 actually includes components other than the components illustrated in FIG. 1, of course, although not illustrated.

WBC system 10 includes a plurality of laser diode bars (hereinafter, referred to as LD bars) 100, optical elements 200, diffraction grating 300, and external resonance mirror 400. Note that, although FIG. 1 illustrates four LD bars, the number is not limited to this obviously. The number of LD bars 100 may be one.

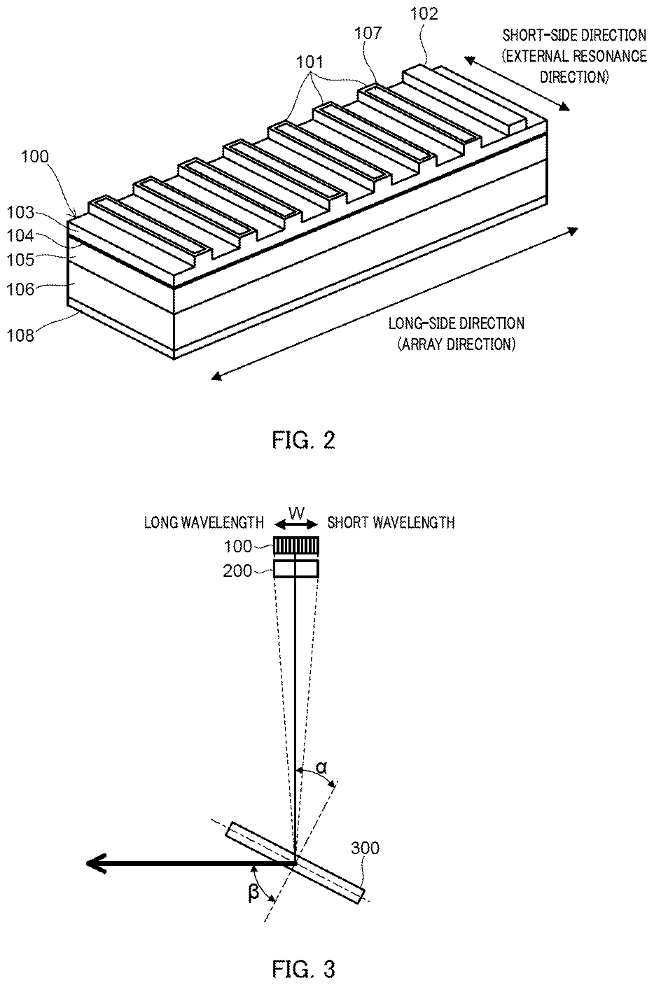

FIG. 2 illustrates a configuration of one LD bar 100. LD bar 100 includes a plurality of emitters 101 and heating element 102.

The plurality of emitters 101 are arranged in stripes in a row along the long-side direction of LD bar 100. The long-side direction is the array direction in which the plurality of emitters 101 are aligned. The plurality of emitters 101 are arranged so that emitters 101 adjacent to each other have equal intervals. Note that, although FIG. 2 illustrates seven emitters 101, the number is not limited to seven obviously.

The plurality of emitters 101 are composed of first conductive cladding layer 103, active layer 104, and second cladding layer 105 stacked together. The plurality of emitters 101 are placed to substrate 106 (e.g., nitride semiconductor substrate).

A plurality of P-type electrodes 107 are placed on the upper surface of LD bar 100 so as to correspond to the plurality of emitters 101. N-type electrode 108 is placed on the lower surface of LD bar 100 with substrate 106 therebetween. When current is supplied in parallel from a power supply unit (not illustrated) to the plurality of P-type electrodes 107, laser oscillation occurs in the plurality of emitters 101, and beams are respectively emitted from the plurality of emitters 101. The beams are emitted simultaneously and parallel to each other from the plurality of emitters 101 along the short-side direction from a surface on one side of the short-side direction of LD bar 100. The short-side direction is the external resonance direction in which external resonance occurs.

Heating element 102 will be described later.

The description continues with reference to FIG. 1 again. The plurality of LD bars 100 are arranged in a row so that their surfaces from which the beams are emitted face diffraction grating 300.

Optical elements 200 condense the beams emitted from the plurality of emitters 101. A plurality of optical elements 200 are arranged between LD bars 100 and diffraction grating 300 so as to correspond to the plurality of LD bars 100. Optical elements 200 are, for example, beam twister lens units. Note that optical elements 200 may be cylindrical lenses, spherical lenses, or mirrors, for example.

Optical elements 200 focus the beams emitted from the plurality of emitters 101 to a single point on the surface of diffraction grating 300. That is, the angle of incidence of the beam emitted from each of the plurality of emitters 101 with respect to diffraction grating 300 changes depending on optical element 200.

Diffraction grating 300 diffracts the beams combined by optical elements 200. Diffraction grating 300 is transmission diffraction grating 300. Note that diffraction grating 300 may be reflection diffraction grating 300.

External resonance mirror 400 is a partially transparent mirror. External resonance mirror 400 vertically reflects some of the incident beam back to diffraction grating 300. Diffraction grating 300 feeds back the beam reflected by external resonance mirror 400 to LD bar 100. Oscillation then occurs between LD bar 100 and external resonance mirror 400 due to external resonance, and a laser beam is emitted from WBC system 10.

WBC system 10 has the following three characteristics.
The oscillation due to external resonance occurs only when the beams emitted from the plurality of emitters 101 meet a diffraction condition of diffraction grating 300 and have a wavelength reflected by external resonance mirror 400.
The wavelength at which the oscillation due to external resonance occurs (hereinafter referred to as a locked wavelength) is uniquely determined by the arrangement of diffraction grating 300 and LD bar 100.
No oscillation due to external resonance occurs when the locked wavelength is not in a range of the wavelengths of the beams emitted from emitters 101 by laser oscillation of emitters 10. When no oscillation due to external resonance occurs in any of the plurality of emitters 101, the output of the laser beam emitted from WBC system 10 is reduced. Note that the range of the wavelengths of the beams emitted from emitters 101 is determined by the configuration of LD bar 100.

The diffraction condition of diffraction grating 300 can be expressed by d (sin α+sin β=mλ, where the period of diffraction grating 300 is d, the angle of incidence is α, the emission angle is β, the wavelength is λ, and the degree is m, in diffraction grating 300. Note that it is common to select diffraction grating 300 that sets 1 as actual effective degree m.

To meet this diffraction condition in conventional WBC system 10, LD bar 100 is designed and manufactured so that LD bar 100 with larger angle of incidence a to diffraction grating 300 emits a beam with a longer wavelength, as illustrated in FIG. 1.

The same applies to emitters 101 aligned on one LD bar 100 illustrated in FIG. 3. As described above, even in one LD bar 100, angle of incidence a of the beam emitted from each of the plurality of emitters 101 with respect to diffraction grating 300 changes depending on optical element 200. That is, to sufficiently meet an external resonance condition, one LD bar 100 should be designed and manufactured so that emitter 101 with larger angle of incidence a to diffraction grating 300 emits a beam with a longer wavelength.

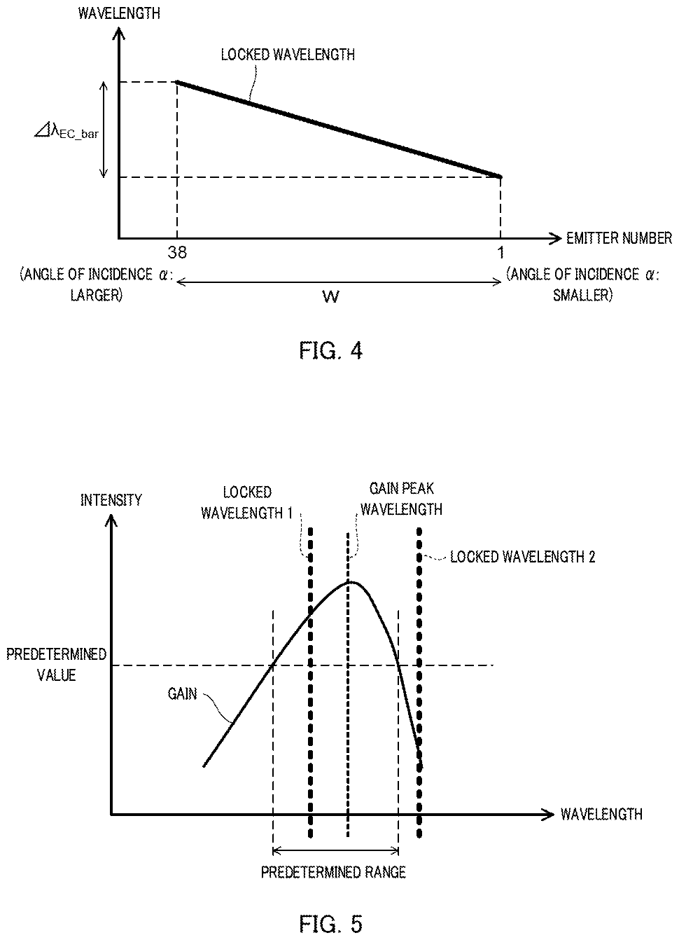

FIG. 4 illustrates exemplary locked wavelengths for respective emitters 101 in one LD bar 100. FIG. 4 illustrates an example in which 38 emitters 101 are formed on one LD bar 100, and the length from first emitter 101 to 38th emitter 101 (length W of LD bar 100 in FIG. 3) is 10 [mm]. Note that, in WBC system 10, LD bar 100 is configured so that emitter 101 with a greater emitter number has larger angle of incidence α. As described above, the larger angle of incidence α is, the longer the locked wavelength is. That is, the greater the emitter number of emitter 101 is, the longer the locked wavelength is.

According to calculations, when length W of LD bar 100 is 10 [mm] and the distance from LD bar 100 to diffraction grating 300 is 2.6 [m], the difference 4-EC bar in the locked wavelength between emitters 101 at both ends of LD bar 100 is approximately 1.0 [nm]. Also, according to calculations, when length W of LD bar 100 is 10 [mm] and the distance from LD bar 100 to diffraction grating 300 is 1.3 [m], the difference 4-EC bar in the locked wavelength between emitters 101 at both ends of LD bar 100 is approximately 2.0 [nm].

FIG. 5 illustrates a relationship between the wavelengths and intensity of beams emitted from the plurality of emitters 101. The curved line in the drawing indicates the gain of laser light generated in emitter 101. In emitter 101, only the laser light with a wavelength within a predetermined range corresponding to a predetermined value or more of the gain is emitted as a beam by laser oscillation. That is, the predetermined range is a range of the wavelengths at which laser oscillation can be performed in emitter 101. The wavelengths within the predetermined range include a gain peak wavelength at which the gain intensity is maximized.

As described above, the locked wavelength is uniquely determined by the arrangement of diffraction grating 300 and the like. Thus, when the locked wavelength is within the predetermined range, oscillation due to external resonance occurs at the locked wavelength. In the example of FIG. 5, the oscillation due to external resonance occurs at locked wavelength 1, which is within the predetermined range. In contrast, no oscillation due to external resonance occurs at locked wavelength 2, which is outside the predetermined range.

Further, the greater the difference between the locked wavelength and the gain peak wavelength is, the smaller the intensity of the gain corresponding to the locked wavelength is. The intensity of the laser beam obtained by external resonance is reduced accordingly. In other words, the smaller the difference between the locked wavelength and the gain peak wavelength is, the greater the intensity of the gain corresponding to the locked wavelength is, thereby preventing the reduction in the intensity of the laser beam emitted from the wavelength beam combining system.

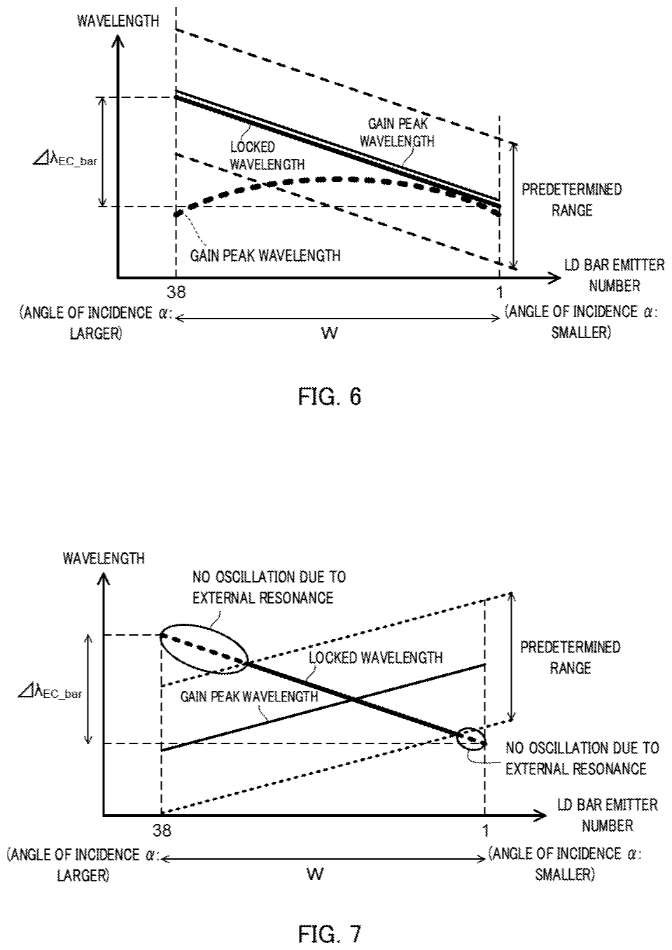

FIGS. 6 and 7 each illustrate a relationship between the gain peak wavelength and the locked wavelength of each emitter 101 of LD bar 100. As described above, the locked wavelength has a slope according to angle of incidence α to diffraction grating 300.

FIG. 6 illustrates an example where distributions of the gain peak wavelength to emitters 101 of LD bar 100, which are indicated by the thin solid line, have a slope in the same direction as that of the locked wavelength indicated by the thick solid line. In the example of FIG. 6, the locked wavelength is within a predetermined range for all emitters 101. Thus, the oscillation due to external resonance occurs in all emitters 101.

In contrast, FIG. 7 illustrates an example where distributions of the gain peak wavelength to emitters 101 of LD bar 100 have a slope opposite to that of the locked wavelength. In the examples of FIG. 7, the locked wavelength is outside the predetermined range for some of emitters 101. Thus, no oscillation due to external resonance occurs in some emitters 101.

Incidentally, the gain peak wavelength is conventionally almost equal for emitters 101 of the same LD bar 100. Accordingly, in the graphs as illustrated in FIGS. 6 and 7, the gain peak wavelength distributions are represented as a straight line with no slope. Thus, considering the relationship with the locked wavelength having a slope, there is a possibility that no oscillation due to external resonance occurs in emitters 101 around both end parts of the long-side direction of LD bar 100.

Further, a plurality of emitters 101 generate heat in LD bar 100 and the plurality of emitters 101 are arranged along the long-side direction; accordingly, the heat is easily built up at the center part of the long-side direction and both end parts of the long-side direction tend to radiate the heat. Thus, in LD bar 100, the temperature at both end parts of the long-side direction is lower than the temperature at the center part of the long-side direction. That is, the center part of the long-side direction has the highest temperature in LD bar 100. In addition, the higher the temperature of emitter 101 is, the longer the wavelength of the beam emitted from emitter 101 is, as described above. In other words, the lower the temperature of emitter 101 is, the shorter the wavelength of the beam emitted from emitter 101 is.

That is, when the temperature at both end parts of the long-side direction is lower than the temperature at the center part of the long-side direction in LD bar 100, the gain peak wavelengths at both end parts of the long-side direction become shorter than the gain peak wavelength at the center part of the long-side direction, as indicated by the thick broken line in FIG. 6. As a result, the larger angle of incidence α is, the greater the difference between the gain peak wavelength and the locked wavelength tends to be, as indicated by the thick broken line in FIG. 6.

The greater the difference between the gain wavelength and the locked peak wavelength is, the smaller the intensity of the gain corresponding to the locked wavelength is (FIG. 5). Accordingly, the intensity of the laser beam emitted from WBC system 10 is reduced.

In addition, when the difference between the gain peak wavelength and the locked wavelength is large and the locked wavelength is outside the predetermined range, no oscillation due to external resonance occurs in emitter 101 corresponding to the locked wavelength outside the predetermined range. In this case, the intensity of the laser beam emitted from WBC system 10 is further reduced.

One of the features of the present disclosure performed under such considerations is to change the temperature distribution in LD bar 100 so that the difference between the gain peak wavelength and the locked wavelength is small. To be more specific, the temperature of LD bar 100 is controlled so that the distribution of the gain peak wavelength follows the distribution of the locked wavelength by utilizing the fact that the higher the temperature of emitter 101 is, the longer the wavelength of the beam emitted from emitter 101 is.

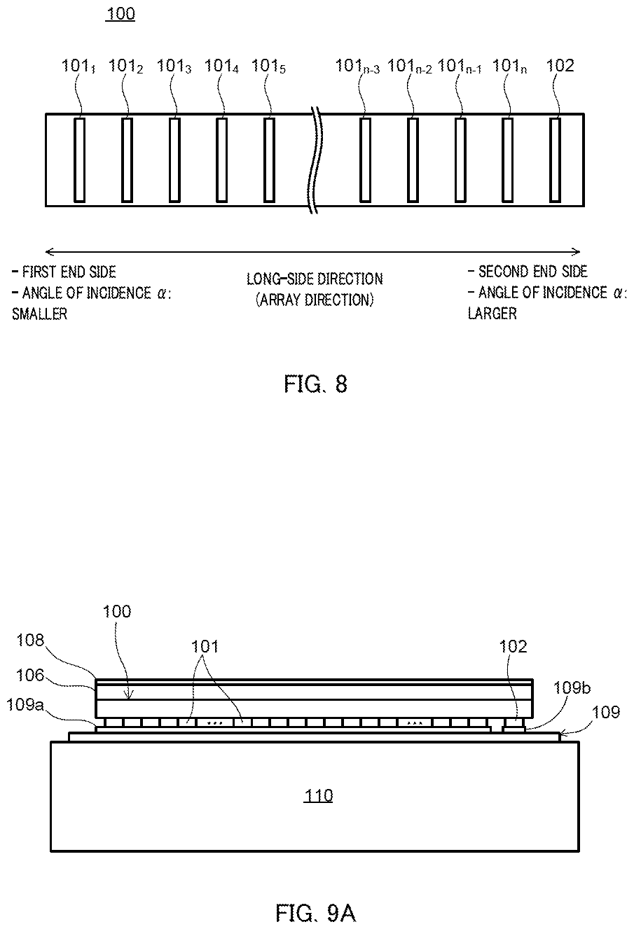

Next, heating element 102 will be described. FIG. 8 is a plan view of one LD bar 100. In FIG. 8, n emitters 101 are aligned along the long-side direction (array direction). In the drawing, the subscripts of the reference sings of emitters 101 indicate the numbers of emitters 101.

N emitters 101 are aligned with equal intervals. First emitter 1011 of n emitters 101 is located at the end part of LD bar 100 on the first end side in the array direction. N-th emitter 101n of n emitters 101 is located at the end part of LD bar 100 on the second end side in the array direction. In WBC system 10, LD bar 100 is placed so that angle of incidence α of the beam is larger from the first end side to the second end side. In addition, the larger angle of incidence α is, the longer the locked wavelength is, as described above. That is, in WBC system 10, LD bar 100 is placed so that the locked wavelength of emitter 101 located on the second end side is longer than the locked wavelength of emitter 101 located on the first end side.

Heating element 102 is located on the upper surface of LD bar 100 on the second end side with respect to the plurality of emitters 101. Heating element 102 is a resistor (e.g., chip resistor) that generates heat with voltage applied. Heating element 102 is supplied with power from an independent power source (e.g., external power source) different from the power supply unit for supplying power to the plurality of emitters 101.

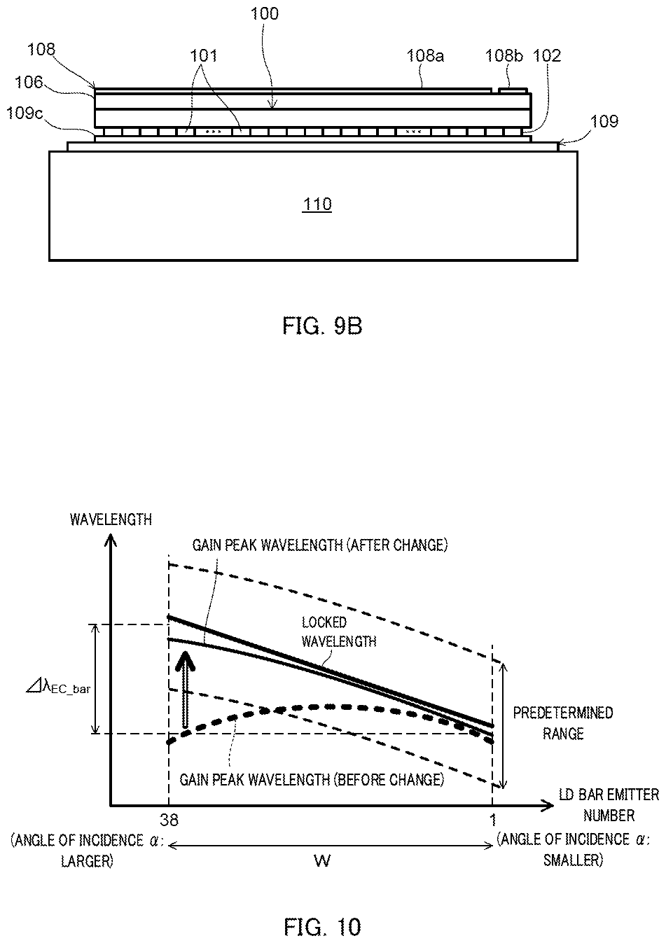

FIG. 9A is a side view illustrating LD bar 100 mounted. LD bar 100 is mounted to sub-mount 109. Sub-mount 109 is, for example, a ceramic substrate. Sub-mount 109 includes first conductive layer 109a and second conductive layer 109b. First conductive layer 109a and second conductive layer 109b are insulated from each other.

First conductive layer 109a is electrically connected to a plurality of P-type electrodes 107. Voltage is applied to the plurality of emitters 101 via first conductive layer 109a and N-type electrode 108. Second conductive layer 109b is electrically connected to heating element 102. Voltage is applied to heating element 102 via second conductive layer 109b and N-type electrode 108.

Note that, as illustrated in FIG. 9B, sub-mount 109 may be configured to include single conductive layer 109c instead of first and second conductive layers 109a and 109b. Conductive layer 109c is electrically connected to the plurality of P-type electrodes 107 and heating element 102. In this case, N-type electrode 108 is configured to include first N-type electrode 108a and second N-type electrode 108b. First N-type electrode 108a and second N-type electrode 108b are insulated from each other. First N-type electrode 108a is located on the lower surface of LD bar 100 at a position corresponding to the plurality of emitters 101. Voltage is applied to the plurality of emitters 101 via conductive layer 109c and first N-type electrode 108a. Second N-type electrode 108b is located on the lower surface of LD bar 100 at a position corresponding to heating element 102. Voltage is applied to heating element 102 via conductive layer 109c and second N-type electrode 108b.

Further, copper block 110 composing a water cooling jacket is located so as to make contact with LD bar 100 via sub-mount 109. Heat of LD bar 100 is released mainly through sub-mount 109 and block 110.

WBC system 10 further includes controlling apparatus 500 that controls power supplied to the plurality of emitters 101 and heating element 102. Controlling apparatus 500 controls power supplied to heating element 102 so that the temperature of heating element 102 is higher than the temperatures of the plurality of emitters 101. To be more specific, controlling apparatus 500 controls power supplied to heating element 102 so as to satisfy Expression 1.

$$\frac{{W}_{t o t}}{n} + \frac{Δ {T}_{chip}}{{R}_{th}} < {W}_{c o n t} < \frac{{W}_{t o t}}{n} + \frac{2 \times Δ {T}_{E C} + Δ {T}_{chip}}{{R}_{th}} \qquad ( Expression 1 )$$

In Expression 1, Wₜₒₜ is the sum of the power supplied to the plurality of emitters 101. The n is the number of emitters 101. ΔT_{chip} is the difference between the temperatures of the center part and the end part on the second end side of LD bar 100. The temperature of the center part of LD bar 100 corresponds to the temperature of emitter 101 located at the center part of LD bar 100. The temperature of emitter 101 is calculated by converting the wavelength of the beam emitted from emitter 101 into the temperature using a temperature coefficient of the beam. The temperature coefficient is a coefficient indicating a relationship between the temperature and wavelength of the beam. The wavelength of the beam is pre-measured before operating WBC system 10. The temperature of the end part of LD bar 100 on the second end side corresponds to the temperature of emitter 101 located at the end part of LD bar 100 on the second end side.

Rₜₕ is thermal resistance of a heat dissipation path of heating element 102. The heat dissipation path of heating element 102 is provided to sub-mount 109 and block 110. That is, Rₜₕ is the sum of the thermal resistance of sub-mount 109 and the thermal resistance of block 110. W_{cont} is the power supplied to heating element 102. ΔT_{EC} is a temperature difference obtained by dividing the difference in the locked wavelengths of emitters 101 at both ends by the temperature coefficient of the beam.

As indicated by the thick broken line in FIG. 6 above, the gain peak wavelength distribution has a slope in the same direction as the slope of the locked wavelength on the side where angle of incidence α decreases from the center part of the long-side direction (on the side where the locked wavelength decreases). Meanwhile, the gain peak wavelength distribution has a slope opposite to the slope of the locked wavelength on the side where angle of incidence α increases from the center part of the long-side direction (on the side where the locked wavelength increases). With this regard, setting power W_{cont} supplied to heating element 102 within the range indicated by Expression 1 makes it possible to change the gain peak wavelength distribution so as to have a slope with an appropriate angle in the same direction as the slope of the locked wavelength over the long-side direction, as described below.

In Expression 1, the first term Wₜₒₜ/n on the left side corresponds to the power supplied to one emitter 101. The second term ΔT_{chip}/Rₜₕ on the left side corresponds to the power supplied to heating element 102 in order for emitter 101 on the second end side (the side where angle of incidence α is larger, the side where the locked wavelength is longer, and the side where heating element 102 is provided) to raise the temperature for the temperature difference between emitter 101 located at the center part of LD bar 100 and emitter 101 located at the end part on the second end side of LD bar 100.

Thus, setting power W_{cont} supplied to heating element 102 larger than Wₜₒₜ/n+ΔT_{chip}/Rₜₕ makes it possible for the temperatures of emitters 101 located on the second end side to be higher than the temperature of emitter 101 located at the center part of LD bar 100. That also increases the gain peak wavelengths of emitters 101 located on the second end side and the upper and lower limits of the wavelength ranges of the beams oscillated from emitters 101. Accordingly, the locked wavelengths of emitters 101 can be included within the range (predetermined range) of the wavelengths of the beams oscillated from emitters 101, as illustrated in FIG. 10.

Note that, when power W_{cont} supplied to heating element 102 is equal to or less than Wₜₒₜ/n+ΔT_{chip}/Rₜₕ, the temperature of heating element 102 is not sufficiently raised, and the upper limit of the predetermined range remains below the locked wavelength for at least some of emitters 101 located on the second end side. In some cases, the gain peak wavelength distribution still has a slope opposite to the slope of the locked wavelength on the side where angle of incidence α increases from the center part of the long-side direction. When the locked wavelength is outside the predetermined range for some of emitters 101 located at the end part on the second end side, possibly no oscillation occurs due to external resonance.

The right side of Expression 1 includes the term 2×ΔT_{EC}/Rₜₕ, compared to the left side. ΔT_{EC}/Rₜₕ corresponds to the power supplied to heating element 102 in order for emitter 101n on the second end side to raise the temperature for the temperature difference, which is based on the difference in the locked wavelength between emitter 101₁ located at the end part on the first end side and emitter 101ₙ located at the end part on the second end side. When heating element 102 is supplied with power less than Wₜₒₜ/n+(2×ΔT_{EC}+ΔT_{chip})/Rₜₕ obtained by adding, to the left side, 2×ΔT_{EC}/Rₜₕ, where an experimentally determined coefficient 2 is multiplied by the above ΔT_{EC}/Rₜₕ, it is possible to increase the gain peak wavelengths of emitters 101 located on the second end side while preventing the lower limit of the predetermined range from exceeding the locked wavelength. Note that the coefficient for ΔT_{EC}/Rₜₕ is set to an appropriate value that is experimentally determined. The coefficient is not limited to 2, and may be set to a value that is 2 or more and 3 or less.

Note that, when power W_{cont} supplied to heating element 102 is equal to or greater than Wₜₒₜ/n+(2×ΔT_{EC}+ΔT_{chip})/Rₜₕ, the temperature of heating element 102 is excessively raised and the lower limit of the predetermined range exceeds the locked wavelength for at least some of emitters 101 located on the second end side. Thus, when the locked wavelength is outside the predetermined range for some of emitters 101 located at the end part on the second end side, possibly no oscillation occurs due to external resonance.

Prior to operating WBC system 10, an operator measures the wavelengths of emitters 101 associated with Expression 1 for each of LD bars 100 and calculates the power to be supplied to heating element 102 based on Expression 1. When controlling WBC system 10, controlling apparatus 500 supplies the power calculated based on Expression 1 to heating element 102. This causes heating element 102 to generate heat.

The heat generated by heating element 102 is transferred to emitters 101 through each of the layers of LD bar 100. Heating element 102 is located on the second end side with respect to the plurality of emitters 101. Thus, the greatest amount of heat is transferred to n-th emitter 101ₙ located on the most second end side, and the amount of heat transferred to emitter 101 becomes less from n-th emitter 101ₙ toward the first end side.

In other words, the amount of heat generated from heating element 102 and transferred to emitter 101 gradually increases from the first end side to the second end side, that is, from the side where angle of incidence α is smaller to the side where it is larger. Thus, the temperature rise of emitter 101 gradually increases from the side where angle of incidence α is smaller to the side where it is larger, and the gain peak wavelength becomes longer in accordance with the temperature rise of emitter 101.

In addition, the power supplied to heating element 102 is set as in Expression 1. This causes the gain peak wavelength distribution to change so as to have a slope with an appropriate angle in the same direction as the slope of the locked wavelength, as illustrated in FIG. 10, so that all the locked wavelengths fall within the predetermined range. Thus, the oscillation due to external resonance occurs in all of the plurality of emitters 101.

Further, the difference between the gain peak wavelength and the locked wavelength is reduced for the plurality of emitters 101, thereby increasing the intensity of the gain corresponding to the locked wavelength and even the intensity of the beam emitted by the oscillation due to external resonance. Accordingly, it is possible to prevent the reduction of the intensity of the laser beam emitted from WBC system 10.

### Embodiment 2

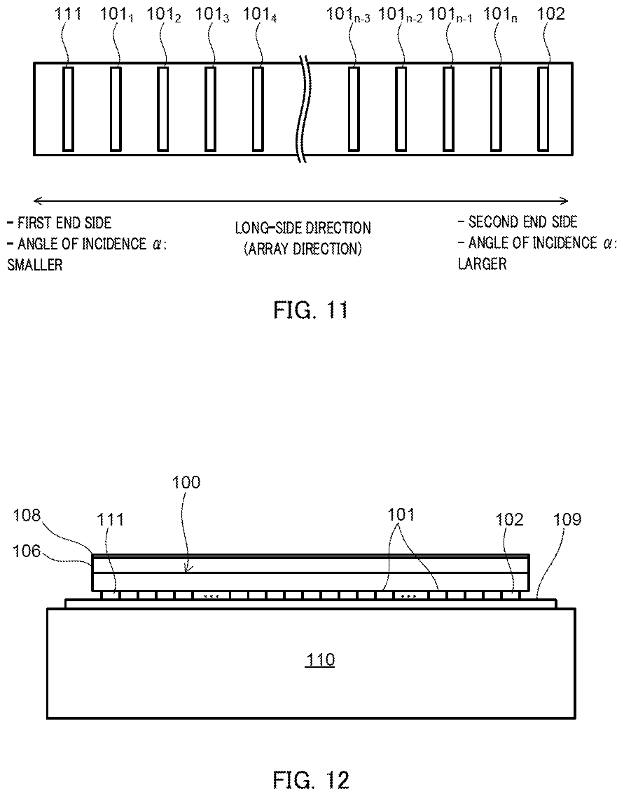

Next, WBC system 10 according to Embodiment 2 of the present disclosure will be described. The description will be mainly for a part different from Embodiment 1. FIG. 11 is a plan view of LD bar 100 according to Embodiment 2. LD bar 100 according to Embodiment 2 includes second heating element 111 in addition to the configuration of LD bar 100 according to Embodiment 1.

Second heating element 111 is located on the upper surface of LD bar 100 on the first end side (on the side where angle of incidence α is smaller and the side where the locked wavelength is shorter) with respect to the plurality of emitters 101. Second heating element 111 is a resistor (e.g., chip resistor) that generates heat with voltage applied. Second heating element 111 is supplied with power from an independent power source different from the power supply unit for supplying power to the plurality of emitters 101 and the power source for supplying power to heating element 102.

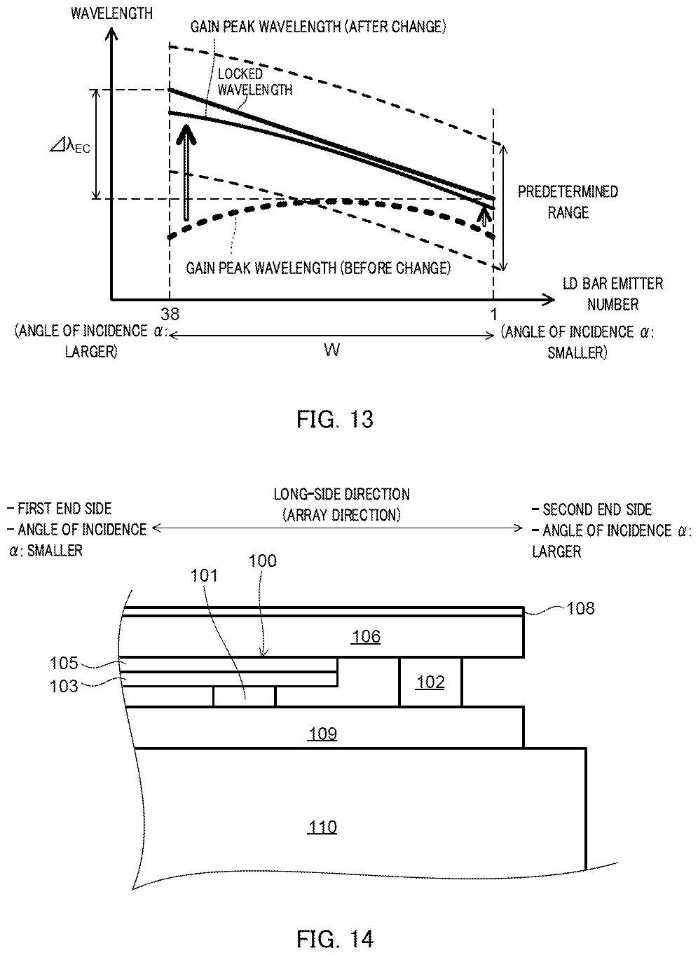

FIG. 12 is a side view illustrating LD bar 100 mounted. Second heating element 111 is mounted to sub-mount 109. Note that the conductive layers are not illustrated in FIG. 12. LD bar 100 according to Embodiment 2 is applied in a case where the difference between the gain peak wavelength and locked wavelength is greater than that of LD bar 100 according to Embodiment 1 as illustrated in FIG. 13.

Controlling apparatus 500 controls power supplied to second heating element 111 so as to meet Expression 2.

$$\frac{{W}_{t o t}}{n} < {W}_{c o n t 2} < \frac{{W}_{t o t}}{n} + \frac{Δ {T}_{c h i p 2}}{{R}_{t h 2}} \qquad ( Expression 2 )$$

In Expression 2, Wₜₒₜ is the sum of the power supplied to the plurality of emitters 101. The n is the number of emitters 101. ΔT_{chip2} is the difference between the temperatures of the center part and the end part on the first end side of LD bar 100. The temperature of the end part of LD bar 100 on the first end side corresponds to the temperature of emitter 101 located at the end part of LD bar 100 on the first end side.

Rₜₕ₂ is thermal resistance of a heat dissipation path of second heating element 111. The heat dissipation path of second heating element 111 is provided to sub-mount 109 and block 110. That is, Rₜₕ₂ is the sum of the thermal resistance of sub-mount 109 and the thermal resistance of block 110. W_{cont2} is the power supplied to second heating element 111.

Power W_{cont} supplied to heating element 102 is set within the range indicated by Expression 1, and power W_{cont2} supplied to second heating element 111 is set within the range indicated by Expression 2. This allows the gain peak wavelength distribution to be changed so as to have a slope with an appropriate angle in the same direction as the slope of the locked wavelength over the long-side direction.

In Expression 2, Wₜₒₜ/n on the left side corresponds to the power supplied to one emitter 101. Thus, setting power W_{cont2} supplied to second heating element 111 larger than Wₜₒₜ/n makes it possible to increase the temperature of emitters 101 located on the first end side. That also increases the gain peak wavelengths of emitters 101 located on the first end side and the upper and lower limits of the wavelength ranges of the beams oscillated from those emitters 101. Accordingly, the locked wavelengths of emitters 101 can be included within the range (predetermined range) of the wavelengths of the beams oscillated from emitters 101, as illustrated in FIG. 13.

Note that, when power W_{cont2} supplied to second heating element 111 is equal to or less than Wₜₒₜ/n, the temperature of second heating element 111 is not sufficiently raised, and the upper limit of the predetermined range remains below the locked wavelength for at least some of emitters 101 located on the first end side. When the locked wavelength is outside the predetermined range for some of emitters 101 located at the end part on the first end side, possibly no oscillation occurs due to external resonance.

The right side of Expression 2 is configured in the same manner as the left side of Expression 1. That is, the first term Wₜₒₜ/n on the right side corresponds to the power supplied to one emitter 101. The second term ΔT_{chip2}/Rₜₕ₂ on the right side corresponds to the power supplied to second heating element 111 in order for emitter 101 on the first end side (the side where angle of incidence α is smaller, the side where the locked wavelength is shorter, and the side where second heating element 111 is provided) to raise the temperature for the temperature difference between emitter 101 located at the center part of LD bar 100 and emitter 101 located at the end part on the first end side of LD bar 100.

Thus, setting power W _{cont2} supplied to second heating element 111 less than Wₜₒₜ/n+ΔT_{chip2}/Rₜₕ₂ makes it possible for the temperatures of emitters 101 located on the first end to be lower than the temperature of emitter 101 located at the center part of LD bar 100. Thus, it is possible to increase the gain peak wavelengths of emitters 101 located on the first end side while preventing the lower limit of the predetermined range from exceeding the locked wavelengths.

Note that, when power W_{cont2} supplied to second heating element 111 is equal to or greater than Wₜₒₜ/n+ΔT_{chip2}/Rₜₕ₂, the temperature of second heating element 111 is excessively raised and the lower limit of the predetermined range exceeds the locked wavelengths for at least some of emitters 101 located on the first end side. When the locked wavelength is outside the predetermined range for some of emitters 101 located at the end part on the first end side, possibly no oscillation occurs due to external resonance.

When the power set by an operator based on Expression 2 is supplied to second heating element 111, the heat generated by second heating element 111 is transferred to emitters 101 through each of the layers of LD bar 100. Second heating element 111 is located on the first end side with respect to the plurality of emitters 101. Thus, the greatest amount of heat is transferred to first emitter 101 located on the most first end side, and the amount of heat transferred to emitter 101 becomes less from first emitter 101 toward the second end side.

Meanwhile, as in Embodiment 1, the operator sets the power between the power calculated from the left side of Expression 1 and the power calculated from the right side to the power supplied to heating element 102. When the power set by the operator based on Expression 1 is supplied to heating element 102, the greatest amount of heat is transferred to n-th emitter 101ₙ located on the most second end side, and the amount of heat transferred to emitter 101 becomes less from n-th emitter 101ₙ toward the first end side, as described above.

Further, the power supplied to heating element 102 is set as in Expression 1, and the power supplied to second heating element 111 is set as in Expression 2. This causes the gain peak wavelength distribution to change so as to have a slope with an appropriate angle in the same direction as the slope of the locked wavelength, as illustrated in FIG. 13, so that all the locked wavelengths fall within the predetermined range. Thus, the oscillation due to external resonance occurs in all of the plurality of emitters 101. In addition, the difference between the gain peak wavelength and the locked wavelength is reduced for the plurality of emitters 101, thereby increasing the intensity of the gain corresponding to the locked wavelength and even the intensity of the beam emitted by the oscillation due to external resonance. Thus, it is possible to prevent the reduction in the intensity of the laser beam emitted from the wavelength beam combining system.

Note that above-described Embodiments 1 and 2 are based on the assumption that the distance (hereinafter, referred to as the optical path length) from LD bar 100 to diffraction grating 300 is fixed. As described above, when length W (FIGS. 3 and 4) of LD bar 100 is 10 [mm] and the optical path length is 2.6 [m], difference ALEC bar in the locked wavelength between emitters 101 at both ends of LD bar 100 is approximately 1.0 [nm], and ΔT_{EC} is approximately 13 [K].

When the optical path length is changed from 1.0 to 4.0 [m] while ALEC bar is kept constant at approximately 1.0 [nm], length W of LD bar 100 is changed from 3.8 to 15 [mm]. When length W of LD bar 100 is less than 3.8 [mm], the difference between the temperatures at the center part and at both ends of LD bar 100 in the long-side direction is small, and the heat generated by heating element 102 is easily transferred to LD bar 100 over the long-side direction.

Meanwhile, when length W of LD bar 100 is greater than 15 [mm], the heat generated by heating element 102 is not easily transferred to the center part of LD bar 100, and only the end part of LD bar 100 on the second end side in the long-side direction is heated. Thus, the temperature distribution in LD bar 100 can be accurately controlled by controlling the power supplied to heating element 102 when length W of LD bar 100 is 3.8 mm to 15 mm. That is, length W of LD bar 100 is preferably in the range from 3.8 to 15 [mm].

### Embodiment 3

Next, WBC system 10 according to Embodiment 3 of the present disclosure will be described. The description will be mainly for a part different from Embodiment 1. In Embodiment 3, heating element 102 is placed on substrate 106 instead of the upper surface of LD bar 100.

The long-side direction of substrate 106 corresponds to the long-side direction of LD bar 100 (FIG. 2). In the long-side direction, the first end side of substrate 106 corresponds to the first end side of LD bar 100, and the second end side of substrate 106 corresponds to the second end side of LD bar 100. That is, LD bar 100 is placed on substrate 106 so that the plurality of emitters 101 are arranged from the first end side to the second end side of substrate 106. In WBC system 10, LD bar 100 is placed so that angle of incidence α of the beam emitted from emitter 101 is larger from the first end side to the second end side of substrate 106. In other words, LD bar 100 is placed so that the locked wavelength of emitter 101 located on the second end side is longer than the locked wavelength of emitter 101 located on the first end side, in WBC system 10.

As illustrated in FIG. 14, heating element 102 is placed on the surface of substrate 106 on which LD bar 100 is placed, on the second end side with respect to LD bar 100. Note that the conductive layers are not illustrated in FIG. 14. Placing heating element 102 on substrate 106 instead of the upper surface of LD bar 100 prevents deterioration of LD bar 100. In addition, it is possible to eliminate the impact of a change in the characteristics of LD bar 100 (e.g., change over time) on the characteristics of heating element 102.

### Embodiment 4

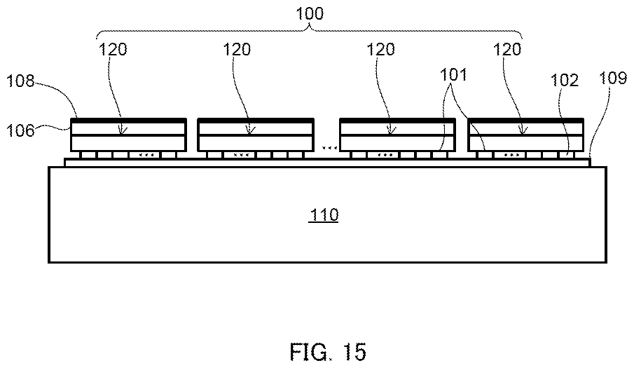

Next, WBC system 10 according to Embodiment 4 of the present disclosure will be described. The description will be mainly for a part different from Embodiment 1. LD bar 100 according to Embodiment 4 is mounted by being divided into a plurality of LD bars 100 as illustrated in FIG. 15. Each of the divided LD bars 100 is referred to as a chip. That is, LD bar 100 is divided into a plurality of chips 120. Substrate 106 and N-type electrode 108 are also divided in accordance with the plurality of chips 120. Note that the conductive layers are not illustrated in FIG. 15.

The interval between adjacent chips 120 is an interval where heat dissipation at both ends of one chip 120 is reduced. Thus, in each of chips 120 located at both ends, the end part that does not face adjacent chip 120 releases heat more than the other end part that faces adjacent chip 120 does.

With this regard, heating element 102 is placed at the end part on the second end side of chip 120 located on the most second end side in the long-side direction. Controlling apparatus 500 controls power supplied to heating element 102 so as to meet Expression 3.

$$\frac{{W}_{t o t 2}}{n} + \frac{Δ {T}_{chip 3}}{{R}_{t h 3}} < {W}_{c o n t 3} < \frac{{W}_{t o t 2}}{n} + \frac{2 \times Δ {T}_{E C 2} + Δ {T}_{chip 3}}{{R}_{th 3}} \qquad ( Expression 3 )$$

In Expression 3, Wₜₒₜ₂ is the sum of the power supplied to the plurality of emitters 101 in chip 120 located on the most second end side. Then is the number of emitters 101 in chip 120 located on the most second end side. ΔT_{chip3} is the difference between the temperatures of the center part and the end part on the second end side of chip 120 located on the most second end side. The temperature of the center part of chip 120 corresponds to the temperature of emitter 101 located at the center part of chip 120. The temperature at the end part on the second end side of chip 120 corresponds to the temperature of emitter 101 located at the end part on the second end side of chip 120.

Rₜₕ₃ is thermal resistance of a heat dissipation path of heating element 102. W_{cont3} is the power supplied to heating element 102. ΔT_{EC2} is a temperature difference obtained by dividing the difference between the locked wavelengths of emitters 101 at both ends of chip 120 located on the most second end side by a temperature coefficient of a beam.

The power supplied to heating element 102 is set as in Expression 3. Expression 3 is configured in the same manner as Expression 1 described above. This causes the gain peak wavelength distribution to change so as to have the same slope as the locked wavelength, so that all the locked wavelengths fall within the predetermined range. Thus, the oscillation due to external resonance occurs in all of the plurality of emitters 101.

As described above, LD bar 100 according to Embodiment 4 is provided by being divided into a plurality of chips 120. Further, LD bar 100 is provided by being cut out from a wafer (not illustrated) having a layered structure of first conductive cladding layer 103, active layer 104, and second conductive cladding layer 105. Thus, dividing LD bar 100 into a plurality of chips 120 makes it possible to use more parts of the wafer as LD bar 100, thereby improving the yield rate of LD bar 100.

The present disclosure is not limited to the embodiments described above. Aspects in which variations are applied to the present embodiments or aspects constructed by combining components in different embodiments may also be included within the scope of the present disclosure without departing from the spirit or scope of the present disclosure.

For example, the power supplied to heating element 102 and second heating element 111 is calculated based on the above expressions, but the power may be predetermined. The predetermined power is derived in advance, for example, by experiments so that the temperature of heating element 102 is higher than the temperatures of the plurality of emitters 101.

In the above embodiments, transmission diffraction grating 300 has been used for the description. Here is a case of reflection diffraction grating 300. Regardless of transmission diffraction grating 300 or reflection diffraction grating 300, in WBC system 10, LD bar 100 is placed so that the locked wavelength of emitter 101 located on the second end side is longer than the locked wavelength of emitter 101 located on the first end side. However, the direction in which angle of incidence α is larger for the reflection diffraction grating is opposite to that for the transmission diffraction grating. That is, in the case of using reflection diffraction grating 300 in WBC system 10, the smaller angle of incidence α is, the longer the locked wavelength is, which is opposite to the case of using transmission diffraction grating 300. Thus, in the case of using reflection diffraction grating 300 in WBC system 10, LD bar 100 is placed so that angle of incidence α of a beam is smaller from the first end side to the second end side.

Accordingly, in the case of using reflection diffraction grating 300 in WBC system 10, LD bar 100 is designed and manufactured so that LD bar 100 with smaller angle of incidence α to diffraction grating 300 emits a beam with a longer wavelength. Also, in the case of using reflection diffraction grating 300, one LD bar 100 is designed and manufactured so that emitter 101 with smaller angle of incidence α to diffraction grating 300 emits a beam with a longer wavelength.

### INDUSTRIAL APPLICABILITY

The present invention is widely applicable to wavelength beam combining systems.

### Reference Signs List

10 Wavelength beam combining system (WBC system)

100 Laser diode bar (LD bar)

101 Emitter

102 Heating element

106 Substrate

111 Second heating element

120 Chip

200 Optical element

300 Diffraction grating

400 External resonance mirror

500 Controlling apparatus

α Angle of incidence

1. A wavelength beam combining system, comprising:
at least one laser diode bar that includes a plurality of emitters arranged in a row from a first end side to a second end side, and a heating element placed on the second end side with respect to the plurality of emitters;
an optical element that condenses a beam emitted from each of the plurality of emitters;
a diffraction grating that diffracts the beam condensed by the optical element;
an external resonance mirror that causes external resonance by feeding back, to the laser diode bar, a part of the beam diffracted by the diffraction grating; and
a controlling apparatus that controls power to be supplied to the plurality of emitters and the heating element, wherein,
the laser diode bar is placed in such a posture that a locked wavelength for at least one of the plurality of emitters located on the second end side is longer than the locked wavelength for at least one of the plurality of emitters located on the first end side, the locked wavelength causing oscillation due to the external resonance, and
the controlling apparatus controls the power to be supplied to the heating element so that a temperature of the heating element is higher than temperatures of the plurality of emitters.

2. The wavelength beam combining system according to claim 1, wherein the controlling apparatus controls the power to be supplied to the heating element so as to meet Expression 1:
$$\frac{{W}_{t o t}}{n} + \frac{Δ {T}_{chip}}{{R}_{th}} < {W}_{c o n t} < \frac{{W}_{t o t}}{n} + \frac{2 \times Δ {T}_{E C} + Δ {T}_{chip}}{{R}_{th}} , \qquad ( Expression 1 )$$
where, in Expression 1, Wₜₒₜ is a sum of the power to be supplied to the plurality of emitters, n is a number of the plurality of emitters, ΔT_{chip} is a temperature difference between a center part and an end part on the second end side of the laser diode bar, Rₜₕ is thermal resistance of a heat dissipation path of the heating element, W_{cont} is the power to be supplied to the heating element, and ΔT_{EC} is a temperature difference resulting from dividing a difference in a plurality of the locked wavelengths for emitters at both ends among the plurality of emitters by a temperature coefficient of the beam.

3. The wavelength beam combining system according to claim 2, wherein,
the laser diode bar further includes a second heating element that is placed on the first end side with respect to the plurality of emitters, and
the controlling apparatus controls power to be supplied to the second heating element so as to meet Expression 2:
$$\frac{{W}_{t o t}}{n} < {W}_{c o n t 2} < \frac{{W}_{t o t}}{n} + \frac{Δ {T}_{c h i p 2}}{{R}_{t h 2}} , \qquad ( Expression 2 )$$
where, in Expression 2, Wₜₒₜ is the sum of the power to be supplied to the plurality of emitters, n is the number of the plurality of emitters, ΔT_{chip2} is a temperature difference between the center part and an end part on the first end side of the laser diode bar, Rₜₕ₂ is thermal resistance of a heat dissipation path of the second heating element, and W_{cont2} is the power to be supplied to the second heating element.

4. The wavelength beam combining system according to claim 1, comprising a plurality of the laser diode bars.

5. A wavelength beam combining system, comprising:
a substrate;
at least one laser diode bar that includes a plurality of emitters and is placed on the substrate so that the plurality of emitters are arranged in a row from a first end side to a second end side of the substrate;
an optical element that condenses a beam emitted from each of the plurality of emitters;
a heating element that is placed on a surface of the substrate on the second end side with respect to the laser diode bar, the surface being a surface on which the laser diode bar is placed;
a diffraction grating that diffracts the beam condensed by the optical element;
an external resonance mirror that causes external resonance by feeding back, to the laser diode bar, a part of the beam diffracted by the diffraction grating; and
a controlling apparatus that controls power to be supplied to the plurality of emitters and the heating element, wherein,
the laser diode bar is placed in such a posture that a locked wavelength for at least one of the plurality of emitters located on the second end side is longer than the locked wavelength for at least one of the plurality of emitters located on the first end side, the locked wavelength causing oscillation due to the external resonance, and
the controlling apparatus controls the power to be supplied to the heating element so as to meet Expression 1:
$$\frac{{W}_{t o t}}{n} + \frac{Δ {T}_{chip}}{{R}_{th}} < {W}_{c o n t} < \frac{{W}_{t o t}}{n} + \frac{2 \times Δ {T}_{E C} + Δ {T}_{chip}}{{R}_{th}} , \qquad ( Expression 1 )$$
where, in Expression 1, Wₜₒₜ is a sum of the power to be supplied to the plurality of emitters, n is a number of the plurality of emitters, ΔT_{chip} is a temperature difference between a center part and an end part on the second end side of the laser diode bar, Rₜₕ is thermal resistance of a heat dissipation path of the heating element, W_{cont} is the power to be supplied to the heating element, and ΔT_{EC} is a temperature difference resulting from dividing a difference in a plurality of the locked wavelengths for emitters at both ends among the plurality of emitters by a temperature coefficient of the beam.
